(19) United States
(12) Patent Application Publication
(10) Pub. No.: US 2006/0068535 A1
(43) Pub. Date: Mar. 30, 2006

(54) Methods of fabricating semiconductor devices

(75) Inventors: Sun-Pil Youn, Seoul (KR); Chang-Won Lee, Gyeonggi-do (KR); Woong-Hee Sohn, Gyeonggi-do (KR); Gil-Heyun Choi, Gyeonggi-do (KR); Jong-Ryeol Yoo, Gyeonggi-do (KR); Dong-Chan Lim, Seoul (KR); Byung-Hak Lee, Gyeonggi-do (KR); Hee-Sook Park, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/216,662

(22) Filed: Aug. 31, 2005

(30) Foreign Application Priority Data
Sep. 4, 2004 (KR) 10-2004-0070636
Dec. 21, 2004 (KR) 10-2004-0109187

(51) Int. Cl. H01L 21/8234

(52) U.S. Cl. 438/197

(57) ABSTRACT

Methods of forming semiconductor devices are provided. A preliminary gate structure is formed on a semiconductor substrate. The preliminary gate structure includes a gate insulation layer pattern, a polysilicon layer pattern and a conductive layer pattern. A first oxidation process is performed on the preliminary gate structure using an oxygen radical. The first oxidation process is carried out at a first temperature. A second oxidation process is carried out on the oxidized preliminary gate structure to provide a gate structure on the substrate, the second oxidation process being carried out at a second temperature, the second temperature being higher than the first temperature.

### CLAIM OF PRIORITY

This application is related to and claims priority from Korean Patent Application No. 2004-70636 filed on Sep. 4, 2004 and Korean Patent Application No. 2004-109187 filed on Dec. 21, 2004, the disclosures of which are hereby incorporated herein by reference as if set forth in their entirety.

### FIELD OF THE INVENTION

The present invention relates to methods of fabricating semiconductor devices and, more particularly, to methods of fabricating semiconductor devices having gate structures that include metal.

### BACKGROUND OF THE INVENTION

As semiconductor devices continue to decrease in size, the fabrication of these structures, as well as the structures themselves, may become complicated. Furthermore, conductive patterns, such as gate electrodes, of the semiconductor devices may have lower resistances as the semiconductor devices become more highly integrated. To reduce the resistance of the gate electrode, a conventional gate electrode of a semiconductor device typically has a polycide structure that includes a polysilicon layer pattern and a metal silicide layer pattern on the polysilicon layer pattern. Recently, gate electrodes of semiconductors have included a polysilicon layer pattern and a metal layer pattern instead of the metal silicide layer pattern. For example, tungsten layer patterns have been used as the metal layer pattern in conventional gate electrodes.

When the tungsten layer pattern is formed on the polysilicon layer pattern to provide the gate electrode, processing conditions for the gate electrode may be adjusted according to characteristics of the tungsten layer pattern so as to correctly form the tungsten layer pattern on the polysilicon layer pattern. Due to the rapid oxidation of the tungsten layer pattern under specific oxidation conditions, adjacent tungsten layer patterns may be electrically connected to each other after the oxidation process. In other words, a bridge may be generated between the adjacent tungsten layer patterns due to the oxidation of the tungsten layer patterns. However, it may be possible to control the oxidation conditions of the oxidation process to reduce the likelihood that the adjacent tungsten layer patterns will be connected by the oxidation of the tungsten layer patterns.

When a gate electrode is oxidized under oxidation conditions that may reduce an oxidation of a surface of a tungsten layer pattern, an oxidizing agent may be diffused into an interface between a gate insulation layer pattern and a polysilicon layer pattern of the gate electrode. Thus, the gate insulation layer may be oxidized to have an irregular thickness, which may cause a threshold voltage of a transistor to vary. Nonvolatile semiconductor memory devices may fail due to variation of the threshold voltage. Furthermore, the gate insulation layer may become thicker after the oxidation process.

When the gate electrode is oxidized at a low temperature in order to obtain a gate insulation layer having a uniform thickness, damage to the gate electrode caused by an etching process may not be sufficiently cured, which may result in a leakage current being generated through the gate electrode. Therefore, conventional nonvolatile semiconductor memory devices including a conventional gate electrode may have poor reliability and electrical characteristics.

### SUMMARY OF THE INVENTION

Some embodiments of the present invention provide methods of forming semiconductor devices. A preliminary gate structure is formed on a semiconductor substrate. The preliminary gate structure includes a gate insulation layer pattern, a polysilicon layer pattern and a conductive layer pattern. A first oxidation process is performed on the preliminary gate structure using an oxygen radical. The first oxidation process is carried out at a first temperature. A second oxidation process is carried out on the oxidized preliminary gate structure to provide a gate structure on the substrate, the second oxidation process being carried out at a second temperature, the second temperature being higher than the first temperature.

In further embodiments of the present invention, performing the second oxidation process may at least partially cure damage to the gate structure caused by an etching process and suppresses oxidation of the conductive layer pattern.

In still further embodiments of the present invention, the conductive layer pattern may include tungsten. The first temperature may include a temperature of from about 200 to about 600° C. The first oxidation process may be followed by forming an oxide layer having a thickness of greater than about SA on a sidewall of the polysilicon pattern.

In some embodiments of the present invention, the second temperature may be from about 700 to about 900° C. Performing the second oxidation process may include performing the second oxidation process using an oxygen gas and a hydrogen gas. In certain embodiments of the present invention, performing the second oxidation process comprises performing the second oxidation process using water vapor and a hydrogen gas.

In further embodiments of the present invention, performing the second oxidation process may include performing the second oxidation process using a furnace type apparatus or a single type apparatus. The gate insulation layer pattern may include silicon oxide or a material having a dielectric constant higher than that of silicon oxide. The material may include HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, CaO and any combination thereof.

### BRIEF DESCRIPTION OF THE DRAWINGS

FIGS. 1 through 11 are cross sections illustrating processing steps in the fabrication of nonvolatile semiconductor devices according to some embodiments of the present invention.

FIGS. 12 through 14 are cross sections illustrating processing steps in the fabrication of field effect transistors according to some embodiments of the present invention.

### DETAILED DESCRIPTION OF EMBODIMENTS OF THE PRESENT INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section may be termed a first region, layer or section without departing from the teachings of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

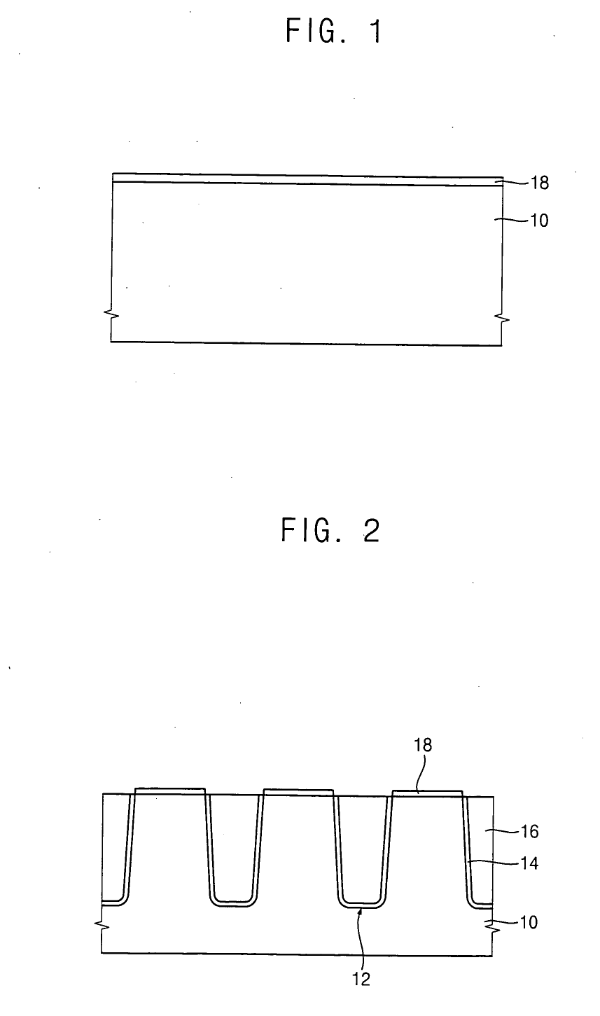

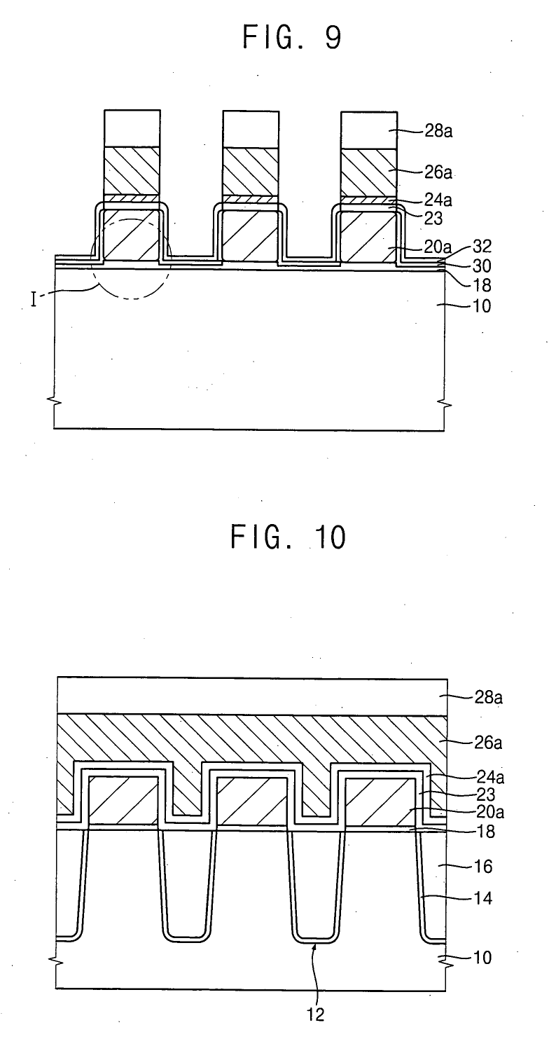

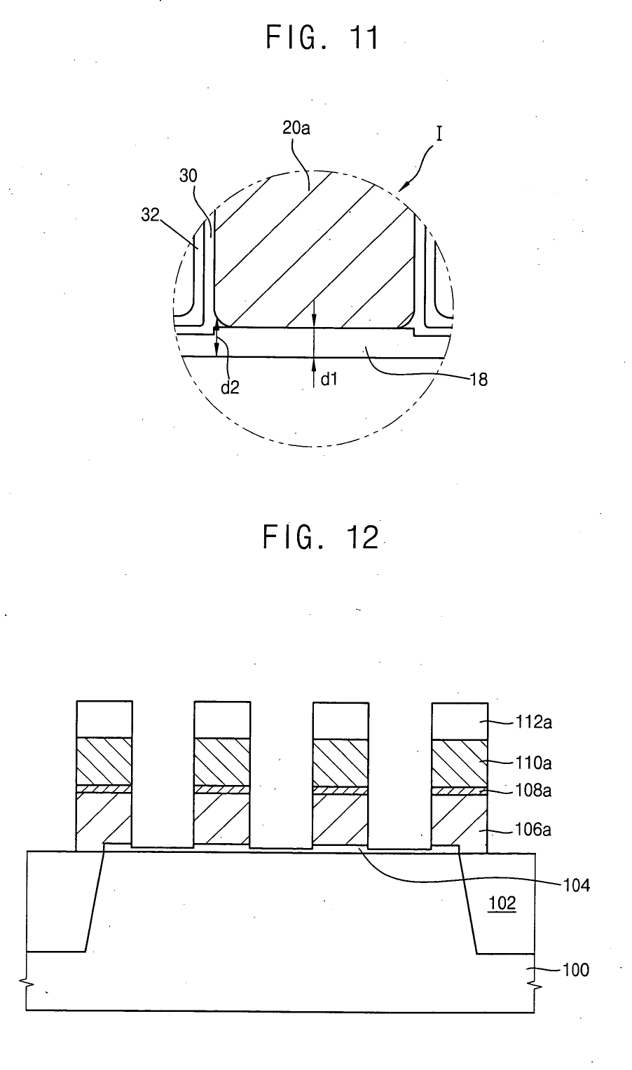

Processing steps in the fabrication of semiconductor devices according to some embodiments of the present invention will be discussed with respect to the cross sections of FIGS. 1 through 11. FIGS. 1, 3 and 7 through 9 are cross sections illustrating the nonvolatile semiconductor device along a first direction parallel to an active region of the nonvolatile semiconductor device. FIGS. 2, 4, 5 and 10 are cross sections illustrating the nonvolatile semiconductor device along a second direction substantially perpendicular to the first direction. FIG. 6 is an enlarged cross section illustrating a dielectric layer of the nonvolatile semiconductor device and FIG. 11 is an enlarged cross section illustrating the selected portion “I” of FIG. 9.

FIGS. 1 and 2 illustrate forming a tunnel oxide layer 18 on a substrate 10. As illustrated in FIGS. 1 and 2, a buffer oxide layer (not shown) is formed on the substrate 10. The substrate 10 may include, for example, a silicon wafer substrate or a silicon on insulator (SOI) substrate. The buffer oxide layer may be formed on the substrate 10 using, for example, a thermal oxidation process or a chemical vapor deposition (CVD) process.

A first hard mask pattern (not shown) is formed on the buffer oxide layer. The first hard mask pattern may be formed using a material that has an etching selectivity relative to the buffer oxide layer and the substrate 10. For example, the first hard mask pattern may include, for example, silicon nitride or silicon oxynitride. Furthermore, the first hard mask pattern may be formed on the buffer oxide layer using, for example, a CVD process. The buffer oxide layer and the substrate 10 are partially etched using the first hard mask pattern as an etching mask, thereby forming a trench 12 at an upper portion of the substrate 10.

A sidewall oxide layer 14 is formed on a sidewall of the trench 12 to cure at least some of the damage to the trench 12 caused during the etching process. The sidewall oxide layer 14 may be formed by, for example, a thermal oxidation process or a CVD process.

An insulation layer is formed on the sidewall oxide layer 14 and the substrate 10 in the trench 12. The insulation layer may include, for example, an oxide. The insulation layer may include, for example, tetra ethyl ortho silicate (TEOS), undoped silicate glass (USG), spin on glass (SOG), high density plasma-chemical vapor deposition (HDP-CVD) oxide, and the like. In addition, the insulation layer may be formed using, for example, a CVD process, an HDP-CVD process, a plasma enhanced chemical vapor deposition process (PE-CVD), an atomic layer deposition (ALD) process, and the like.

The insulation layer is partially removed using, for example, a chemical mechanical polishing (CMP) process, an etch back process or a combination process of CMP and etch back until the at least a portion of the substrate 10 is exposed. Thus, an isolation layer 16 is formed in the trench 12. When the isolation layer 16 is formed in the trench 12, the active region and a field region are defined.

The first hard mask pattern and the buffer oxide layer are removed from the substrate 10 and the tunnel oxide layer 18 is formed on the active region of the substrate 10. The tunnel oxide layer 18 may be formed using, for example, a thermal oxidation process or a CVD process. The tunnel oxide layer 18 may have a varied thickness based on desired electrical characteristics of the nonvolatile semiconductor device. For example, the tunnel oxide layer 18 may have a thickness of from about 50 to about 200 Å when the nonvolatile semiconductor device has a design rule of below about 100 nm.

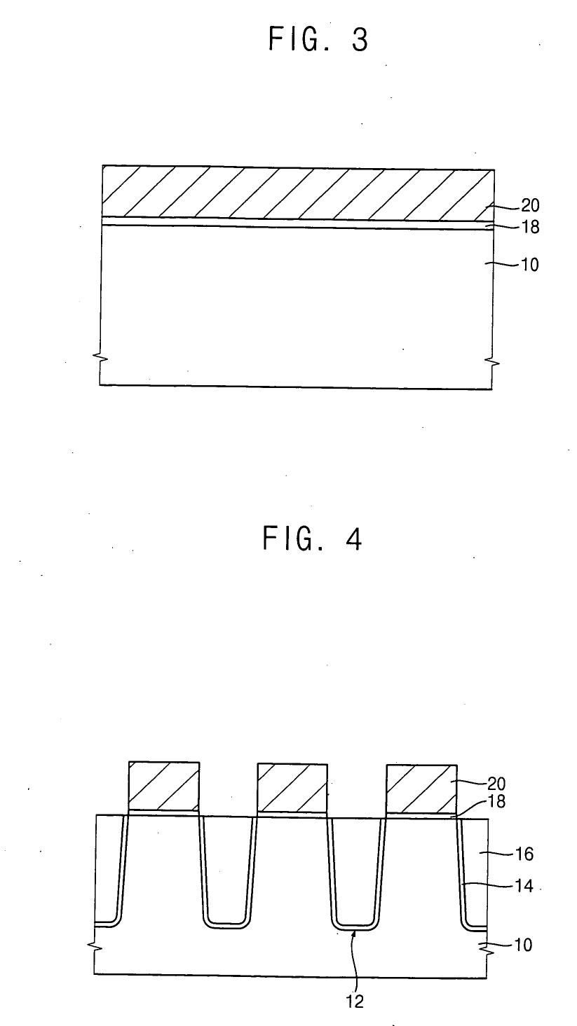

Referring now to FIGS. 3 and 4, cross-sections illustrating processing steps in the formation of a preliminary polysilicon layer pattern 20 on the tunnel oxide layer 18 will be discussed. As illustrated in FIGS. 3 and 4, a polysilicon layer doped with impurities is formed on the tunnel oxide layer 18. The polysilicon layer may be doped with p- type or n-type impurities. The polysilicon layer is patterned to form a floating gate electrode of the nonvolatile semiconductor device in a subsequent process. The polysilicon layer may be formed using, for example, a CVD process, a PE-CVD process, an ALD process, and the like. Furthermore, the polysilicon layer may be doped using, for example, a diffusion process, an ion implantation process or an in-situ doping process.

Although the polysilicon layer may be doped with p-type impurities, n-type impurities may be provide improved electrical characteristics in the floating gate of the nonvolatile semiconductor device. The polysilicon layer may be partially etched along the first direction to thereby form the preliminary polysilicon layer pattern 20 on the tunnel oxide layer 18.

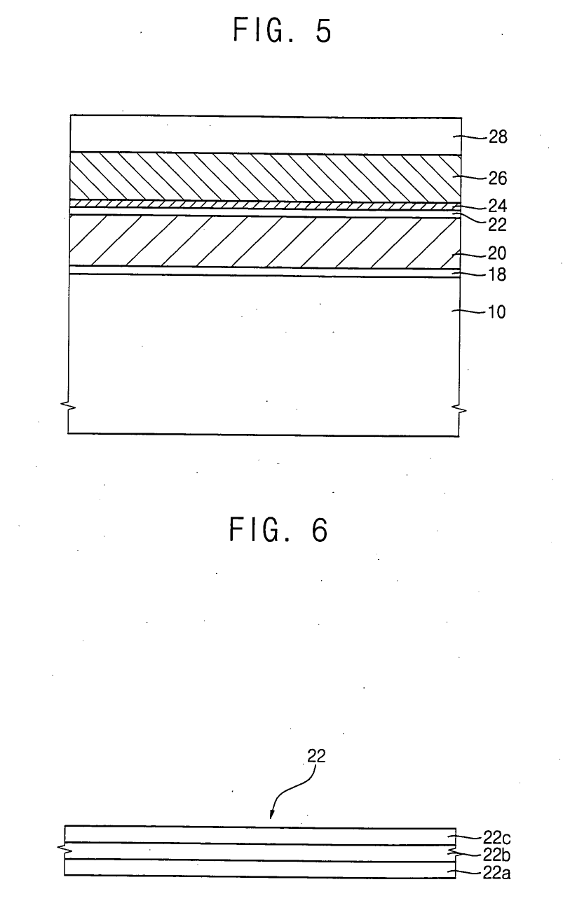

Referring now to FIG. 5, a cross section illustrating processing steps in the fabrication of a dielectric layer 22, a barrier layer 24, a conductive layer 26 and a second hard mask layer 28 on the preliminary polysilicon layer pattern 20 will be discussed. FIG. 6 is an enlarged cross section illustrating the dielectric layer 22 in FIG. 5.

Referring to FIG. 5, the dielectric layer 22 is formed on the preliminary polysilicon layer pattern 20. The dielectric layer 22 may be very thin to improve a coupling ratio of the nonvolatile semiconductor device. Hence, the dielectric layer 22 may be formed using a material that has a thin equivalent oxide thickness (EOT) and a high dielectric constant. When the dielectric layer 22 includes the material having the high dielectric constant, a leakage current through the dielectric layer 22 may be reduced. The dielectric layer 22 may be formed using, for example, a metal oxide. The metal oxide may include, but is not limited to, HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, CaO and any combination thereof.

In some embodiments of the present invention, the dielectric layer 22 may include a silicon oxide film 22a, a silicon nitride film 22b and a metal oxide film 22c as illustrated in FIG. 6. In these embodiments, the metal oxide film 22c may include at least one of the above-mentioned metal oxides. The silicon oxide film 22a, the silicon nitride film 22b and the metal oxide film 22c are sequentially formed on the preliminary polysilicon layer pattern 20. In further embodiments of the present invention, the dielectric layer 22 may include a metal oxide film. In still further embodiments of the present invention, the dielectric layer 22 may have an oxide/nitride/oxide (ONO) structure that includes a lower oxide film, a nitride film and an upper oxide film sequentially formed on the preliminary polysilicon layer pattern 20.

The barrier layer 24 is formed on the dielectric layer 22. The barrier layer 24 may reduce the likelihood that metal atoms included in the conductive layer 26 will diffuse into the preliminary polysilicon layer 20. The barrier layer 24 may be formed using, for example, a metal nitride. For example, in some embodiments of the present invention, the barrier layer 24 is formed using tungsten nitride. Furthermore, the barrier layer 24 may be formed using, for example, a sputtering process, a CVD process, an ALD process, a pulse laser deposition (PLD) process, and the like. The barrier layer 24 may have a thickness of from about 30 to about 100 Å.

The conductive layer 26 is formed on the barrier layer 24. The conductive layer 26 may be formed using a conductive material such as a metal. For example, the conductive layer 26 is formed using tungsten. The conductive layer 26 may be formed by a sputtering process, a chemical vapor deposition (CVD) process, an atomic layer deposition (ALD) process, a pulsed layer deposition (PLD) process, and the like. The conductive layer 26 may be patterned to form a control gate of the nonvolatile semiconductor device.

The second hard mask layer 28 is formed on the conductive layer 26. The second hard mask layer 28 may be formed using, for example, a CVD process, a plasma enhanced (PE) CVD process, an ALD process, and the like. The second hard mask layer 28 may be formed using a nitride, such as silicon nitride.

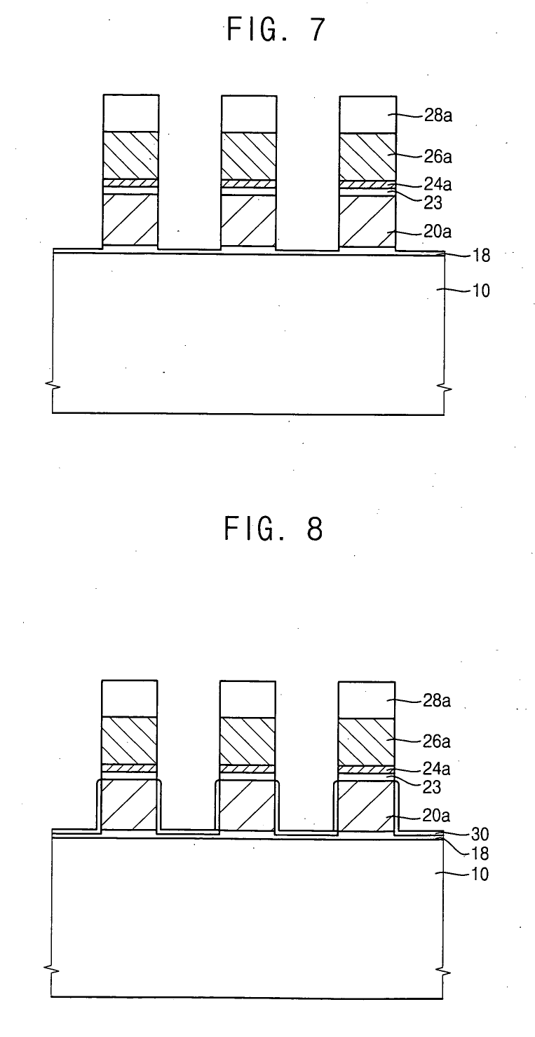

Referring now to FIG. 7, a cross section illustrating processing steps in the fabrication of preliminary gate structures on the substrate 10 according to some embodiments of the present invention will be discussed. As illustrated in FIG. 7, the second hard mask layer 28 is patterned to form a second hard mask pattern 28a on the conductive layer 26. The conductive layer 26, the barrier layer 24, the dielectric layer 22 and the preliminary polysilicon layer pattern 20 are partially etched using the second hard mask pattern 28a as an etching mask to provide the preliminary gate structure on the tunnel oxide layer 18. The tunnel oxide layer 18 may remain on at least a portion of the surface of the substrate 10 to reduce the likelihood that the active region of the substrate 10 will be damaged during the etching process. In embodiments of the present invention not including the tunnel oxide layer 18 on the substrate 10, the substrate 10 may be damaged in the etching process, for example, active pitting may be generated in the active region of the substrate 10.

As illustrated in FIG. 7, the preliminary gate structure includes a polysilicon layer pattern 20a, a dielectric layer pattern 23, a barrier layer pattern 24a, and a conductive layer pattern 26a successively formed on the tunnel oxide layer 18. In some embodiments of the present invention, adjacent polysilicon layer patterns 20a may be separated from each other along the first direction. Additionally, the dielectric layer pattern 23, the barrier layer pattern 24a and the conductive layer pattern 26a may have line shapes in the second direction.

Referring now to FIG. 8, a cross section illustrating processing steps in the fabrication of a first oxide layer 30 on a sidewall of the polysilicon layer pattern 20a and the tunnel oxide layer 18 according to some embodiments of the present invention will be discussed. As illustrated in FIG. 8, a first oxidation process is performed on the substrate 10 having the preliminary gate structure. The first oxidation process may be a first re-oxidation process when the tunnel oxide layer 18 is formed by the oxidation process. The first oxidation process may be carried out using, for example, oxygen radicals as a first oxidant. In the first oxidation process, an oxygen (O₂) gas, a hydrogen (H₂) gas and an argon (Ar) gas are introduced into a chamber wherein the substrate 10 having the preliminary gate structure is loaded. Then, oxygen radicals (O*) and hydroxide radicals (OH*) are generated in the chamber so that the first oxide layer 30 is formed on the tunnel oxide layer 18 and on the sidewall of the polysilicon layer pattern 20a. In some embodiments of the present invention, the argon gas may not be provided into the chamber because the argon gas is introduced so as to rapidly form the oxygen radicals (O*) and the hydroxide radicals (OH*). In further embodiments of the present invention, the first oxide layer 30 may be rapidly formed when the argon gas is introduced into the chamber. In some embodiments of the present invention, a flow rate ratio of the oxygen gas relative to the hydrogen gas may be in a range of from about 1.0 to about 1,000 percent. The first oxide layer 30 may be formed under a pressure of from about 1.0 to about 10 Torr by applying a power of from about 1,000 to about 5,000 W.

The first oxide layer 30 may reduce the likelihood that a second oxidant is diffused into the tunnel oxide layer 18 beneath the polysilicon layer pattern 20a in subsequent processes. In other words, the first oxide layer 30 may serve as a diffusion barrier layer relative to the oxidant. The first oxide layer 30 may have a thickness of greater than about 5 Å measured from a surface of the polysilicon layer pattern 20a, because a thickness of less than about 5 Å may not reduce the likelihood of the diffusion of the oxidant. Thus, in some embodiments of the present invention, the first oxide layer 30 may have a thickness of greater than about 10 Å.

In some embodiments of the present invention, the first oxidation process may be performed at a temperature of from about 200 to about 600° C. In further embodiments of the present invention, the first oxidation process may be carried out at a temperature of from about 250 to about 300° C. Since the first oxidation process is executed at the temperature that may be substantially lower than that of a conventional wet thermal oxidation process or a dry thermal oxidation process, the tunnel oxide layer 18 may not be re-oxidized. In particular, the oxidant may not be diffused into an interface between the polysilicon layer pattern 20a and the tunnel oxide layer 18 so that the tunnel oxide layer 18 may not be re-oxidized. In some embodiments of the present invention, the etched damage to the polysilicon layer pattern 20a may be cured at the low temperature.

FIGS. 9 and 10 are cross sections illustrating processing steps in the fabrication of a gate structure on the substrate 10 according to some embodiments of the present invention. FIG. 11 is an enlarged cross section illustrating the isolated region “I” in FIG. 9. Referring now to FIGS. 9 through 11, a second oxidation process is performed on the preliminary gate structure to thereby form the gate structure on the tunnel oxide layer 18. The second oxidation process may be a re-oxidation process when the tunnel oxide layer 18 is formed by the oxidation process.

A second oxide layer 32 is formed on the first oxide layer 30. The second oxidation process is carried out while suppressing an oxidation of a surface of the conductive layer pattern 26a. The gate structure includes the polysilicon layer pattern 20a, the first oxide layer 30, the second oxide layer 32, the dielectric layer pattern 23, the barrier layer pattern 24a, and the conductive layer pattern 26a. The second oxidation process may be executed using, for example, a furnace type apparatus or a single type apparatus.

In the second oxidation process, an oxygen gas or a gas including oxygen may be provided on the first oxide layer 30 as the second oxidant. Furthermore, a hydrogen gas may be simultaneously provided with the second oxidant. For example, an oxygen gas and a hydrogen gas are used for forming the second oxide layer 32 in the second oxidation process. In some embodiments of the present invention, a water (H₂O) vapor or a hydrogen gas may be used for forming the second oxide layer 32.

In embodiments of the present invention where the second oxide layer 32 is formed using the oxygen gas and the hydrogen gas, a formation rate of the second oxide layer 32 may depend on a partial pressure ratio of the oxygen gas relative to the hydrogen gas. The second oxide layer 32 may be formed by increasing the partial pressure of the oxygen gas, whereas the oxidation of the conductive layer pattern 26a may be suppressed by increasing the partial pressure of the hydrogen gas. Hence, the partial pressure ratio of the oxygen gas relative to the hydrogen gas may be in a range of from about 1.0 to about 1,000 percent.

In embodiments of the present invention where the second oxide layer 32 is formed using the water vapor and the hydrogen gas, a partial pressure ratio of the water vapor relative to the hydrogen gas may be in a range of from about 25 to about 75 percent. In embodiments of the present invention where a partial pressure ratio of the water vapor relative to the hydrogen gas is greater than about 75 percent, the conductive layer pattern 26a may be partially oxidized.

The second oxidation process may be carried out at a higher relative temperature than that of the first oxidation process. For example, the second oxidation process may be performed at a temperature of from about 700 to about 90020 C. When the second oxidation process is performed at the relatively high temperature, the damage to the gate structure caused by the etch may be sufficiently cured. Additionally, any damage to the substrate 10 generated in the formation of the trench 12 may be effectively cured after the second oxidation process.

In some embodiments of the present invention, the damage to the substrate 10 may be partially cured in accordance with the formation of the sidewall oxide layer 14. Furthermore, the etched damage to the substrate 10 may be sufficiently cured through the second oxidation process. Therefore, the likelihood that a leakage current will be generated by the damage to the substrate 10 may be significantly reduced after the second oxidation process. That is, when the second oxidation process is performed at the relatively high temperature, the etched damage to the substrate 10 may be substantially cured so that the leakage current flowing into the substrate 10 is significantly reduced, if not prevented.

Since the second oxidation process is carried out at the temperature of from about 700 to about 900° C., the diffusion of the second oxidant may be accelerated. The second oxidant may be rapidly diffused into an interface between the tunnel oxide layer 18 and the polysilicon layer pattern 20a rather than the bulk tunnel oxide layer 18 because some defects may be generated at the interface between the tunnel oxide layer 18 and the polysilicon layer pattern 20a. When the second oxidant is diffused toward a central portion of the tunnel oxide layer 18 from the interface between the first oxide layer 30 and the polysilicon layer pattern 20a, a bird's beak phenomenon may be generated in the tunnel oxide layer 18 so that the tunnel oxide layer 18 may have an irregular thickness. In particular, the bird's beak phenomenon of the tunnel oxide layer 18 may be enhanced when the second oxidation process is executed using the hydrogen gas. However, because the first oxide layer 30 is provided on the tunnel oxide layer 18 and the sidewall of the polysilicon layer pattern 20a, the second oxidant may not be diffused into the interface between the tunnel oxide layer 18 and the polysilicon layer pattern 20a in the second oxidation process. Therefore, the tunnel oxide layer 18 may have an improved uniformity due to the first oxide layer 30. Furthermore, the likelihood that the nonvolatile semiconductor device will fail due to the bird's beak phenomenon may significantly reduced so that etched damages to the substrate 10 and the gate structure may be sufficiently cured after the second oxidation process.

When source/drain regions are formed adjacent to the gate structure and wirings are formed on the substrate 10, the nonvolatile semiconductor device may be formed on the substrate 10.

Various examples according to embodiments of the present invention will be discussed. According to Example 1, after a first tunnel oxide layer was formed on a substrate, a first gate structure was formed on the first tunnel oxide layer by processing substantially similar to the processing steps described above with reference to FIGS. 1 to 11. Then, a thickness of the first tunnel oxide layer and a length of the first gate structure were measured. The measured thickness of the first tunnel oxide layer was about 61 Å, and the measured length of the first gate structure was about 650 Å.

A first oxidation process was performed using a chamber under processing conditions that included flow rates of an argon (Ar) gas, a hydrogen (H₂) gas and an oxygen (O₂) gas that were about 1,000 sccm, about 300 sccm and about 100 sccm, respectively. In addition, an applied power was about 3,500 W and a temperature of the chamber was about 250° C. After the first oxidation process, a first oxide layer had a thickness of about 60 Å based on a bare wafer.

A second oxidation process was carried out using a furnace type apparatus under process conditions that included a temperature of the chamber that was about 850° C., and a partial pressure ratio of a hydrogen gas relative to the oxygen gas that was about 55 percent. A second oxide layer had a thickness of about 10 Å based on a bare wafer after the second oxidation process.

According to a first comparative example, after a second tunnel oxide layer was formed on a substrate, a second gate structure was formed on the substrate by processing steps substantially similar to the processing steps discussed above with respect to Example 1. However, a first oxidation process was not performed about the second gate structure and the second tunnel oxide layer.

According to a second comparative example, after a third tunnel oxide layer was formed on a substrate, a third gate structure was formed on the substrate using processing steps substantially similar to the processing steps discussed above with respect to Example 1. However, a second oxidation process was not executed about the third gate structure and the third tunnel oxide layer.

Measurements of thicknesses of tunnel oxide layers according to some embodiments of the present invention will now be discussed. A central portion of the first tunnel oxide layer of Example 1 had a thickness of about 61 Å, which is shown as “d1” in FIG. 11. An edge portion of the first tunnel oxide layer had a thickness of from about 64 to about 68 Å, which is shown as “d2” in FIG. 11. After the first and the second oxidation processes, the first tunnel oxide layer of Example 1 was not affected by the bird's beak phenomenon. That is, the thickness of the central portion of the first tunnel oxide layer was not augmented. The bird's beak phenomenon was generated at the edge portion of the first tunnel oxide layer so that a polysilicon layer pattern was rounded as shown in FIG. 11. Since the polysilicon layer pattern had the rounded portion adjacent to the edge portion of the first tunnel oxide layer, an electric field may not be concentrated at an edge portion of the polysilicon layer pattern and also a leakage current may not be generated through the edge portion of the first tunnel oxide layer.

An edge portion of the second tunnel oxide layer of the first comparative example had a thickness of about 71 A, and a central portion of the second tunnel oxide layer had a thickness of about 64 Å. Thus, the second tunnel oxide layer of the first comparative example had the irregularly thick central portion due to the bird's beak phenomenon.

An edge portion of the third tunnel oxide layer of the second comparative example had a thickness of about 64 Å, and a central portion of the third tunnel oxide layer had a thickness of about 61 Å. In the second comparative example, the edge portion of the third tunnel oxide layer was not significantly thickened, although the third tunnel oxide layer had slightly thick central portion. Thus, a polysilicon layer pattern on the third tunnel oxide layer did not have a rounded edge portion, thereby causing the concentration of an electric field and the generation of the leakage current.

FIGS. 12 to 14 are cross sections illustrating processing steps in the fabrication of field effect transistors according to some embodiments of the present invention. The processing steps in the fabrication of the field effect transistors are substantially similar to the processing steps in the fabrication of the nonvolatile semiconductor devices discussed above. However, the processing steps in the fabrication of the dielectric layer may be different.

In particular, as illustrated in FIG. 12, an isolation layer 102 is formed at an upper portion of a substrate 100 by an STI process to define an active region and a field region. A gate insulation layer 104 is formed on the active region of the substrate 100. The gate insulation layer 104 may be formed by, for example, a thermal oxidation process. The gate insulation layer 104 may be formed using, for example, silicon oxide or a material having a dielectric constant substantially higher than that of silicon oxide. For example, the gate insulation layer 104 may be formed using a metal oxide such as HfO₂, ZrO₂, Ta₂O5, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅ or CaO and any combination thereof. The gate insulation layer 104 may be formed by a sputtering process, a CVD process, an ALD process and the like.

A polysilicon layer doped with n-type or p-type impurities is formed on the gate insulation layer 104. The polysilicon layer will be patterned to form a gate electrode. When an n-type transistor is formed on the substrate 100, a polysilicon layer doped with the n-type impurities is formed on the gate insulation layer 104. On the other hand, a polysilicon layer doped with the p-type impurities is formed on the gate insulation layer 104 when a p-type transistor is formed on the substrate 100. As for a volatile semiconductor device such as a dynamic random access memory (DRAM) device, a unit cell of the DRAM device includes n-type transistors so that a polysilicon layer doped with n-type impurities is formed in the unit cell.

A barrier layer is formed on the polysilicon layer. The barrier layer may have a thickness of from about 30 to about 100 Å. The barrier layer may be formed using a metal nitride such as tungsten nitride. The barrier layer prevents metal atoms included in a conductive layer from diffusing into the polysilicon layer. The conductive layer is formed on the barrier layer. The conductive layer may be formed using a metal, such as tungsten. The conductive layer may reduce a resistance of the gate electrode. A hard mask layer is formed on the conductive layer. The hard mask layer may be formed using a nitride such as silicon nitride. The hard mask layer is partially etched by a photolithography process to thereby form a hard mask pattern 112a on the conductive layer.

The conductive layer, the barrier layer and the polysilicon layer are sequentially etched using the hard mask pattern 112a as an etching mask so that a preliminary gate structure is formed on the gate insulation layer 104. The preliminary gate structure includes a polysilicon layer pattern 106a, a barrier layer pattern 108a and a conductive layer pattern 110a.

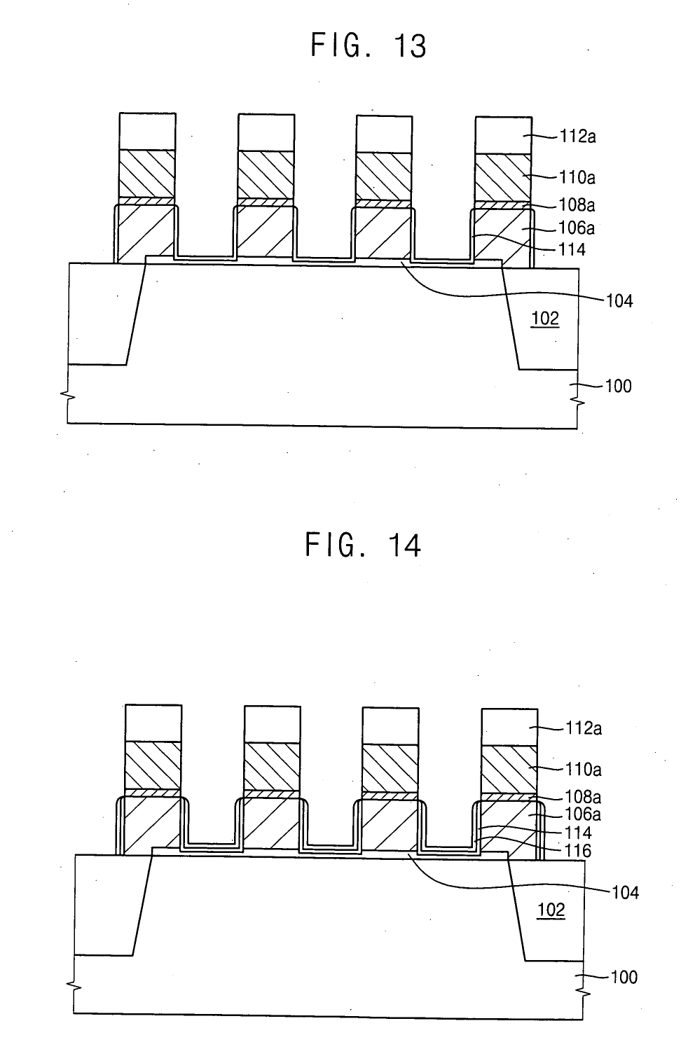

Referring now to FIG. 13, a first oxidation process is carried out about the substrate 100 having the preliminary gate structure thereon after the substrate 100 is loaded in a chamber. The first oxidation process is referred to as a first re-oxidation process because the gate insulation layer 104 is formed by the thermal oxidation process. In the first oxidation process, an oxygen gas, a hydrogen gas and an argon gas are introduced in the chamber, and then oxygen radicals (O*) and hydroxide radicals (OH*) are generated in the chamber.

A first oxide layer 114 is formed on the gate insulation layer 104 and a sidewall of the polysilicon layer pattern 106a using the oxygen radicals and the hydrogen radicals. The first oxide layer 114 may reduce the likelihood that an oxidant will diffuse into an interface between the polysilicon layer pattern 106a and the gate insulation layer 104 in a successive second oxidation process. The first oxidation process may be executed at a temperature of from about 200 to about 600° C.

Referring now to FIG. 14, the second oxidation process is performed on the substrate 100 having the preliminary gate structure and the first oxide layer 114, thereby forming a gate structure on the substrate 100. The second oxidation process is referred to as a second re-oxidation process when the gate insulation layer 104 is formed by the thermal oxidation process. The second oxidation process is executed to form a second oxide layer 116 on the first oxide layer 114 while suppressing an oxidation of the conductive layer pattern 110a.

In the second oxidation process, an oxygen gas or a gas containing oxygen is provided on the substrate 100 together with a hydrogen gas so as to form the second oxide layer 116 whereas the conductive layer pattern 110a is not oxidized. For example, an oxygen gas and a hydrogen gas are provided to form the second oxide layer 116. Alternatively, a water vapor and a hydrogen gas are used for forming the second oxide layer 116. The second oxidation process is carried out at a temperature that is relatively higher than that of the first oxidation process. For example, the second oxidation process may be performed at a temperature of from about 700 to about 900° C.

When the second oxidation process is executed at a high temperature, etch damage to the gate structure may be thermally cured, and also etch damage to the substrate 100 generated in a formation of the isolation layer 102 may be cured. Since the first oxide layer 114 is provided on the gate insulation layer 104 and the sidewall of the polysilicon layer pattern 106a, the oxidant may not be diffused into the interface between the polysilicon layer pattern 106a and the first oxide layer 114 in the second oxidation process. Therefore, the gate insulation layer 104 may have a uniform thickness without an irregular increase of a thickness thereof. After source/drain regions are formed adjacent to the gate structure, the field effect transistor is formed on the substrate 100.

As discussed above with respect to the Figures, damage caused to a gate structure by an etching process may be sufficiently cured whereas a re-oxidation of a tunnel oxide layer or a gate insulation layer may be reduced. Thus, a leakage current through tunnel oxide layer or the gate insulation layer may be substantially reduced. Furthermore, a variation of a threshold voltage of a semiconductor device having the gate structure may be reduced by reducing the likelihood that the tunnel oxide layer or the gate insulation layer will be re-oxidized. As a result, semiconductor devices according to some embodiments of the present invention may have an improved reliability and enhanced electrical characteristics.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A method of forming a semiconductor device comprising:
forming a preliminary gate structure on a semiconductor substrate, the preliminary gate structure including a gate insulation layer pattern, a polysilicon layer pattern and a conductive layer pattern;
performing a first oxidation process on the preliminary gate structure using an oxygen radical, the first oxidation process being carried out at a first temperature; and
performing a second oxidation process on the oxidized preliminary gate structure to provide a gate structure on the semiconductor substrate, the second oxidation process being carried out at a second temperature, the second temperature being higher than the first temperature.

2. The method of claim 1, wherein performing the second oxidation process at least partially cures damage to the gate structure caused by an etching process and suppresses oxidation of the conductive layer pattern.

3. The method of claim 1, wherein the conductive layer pattern comprises tungsten.

4. The method of claim 1, wherein the first temperature comprises a temperature of from about 200 to about 600° C.

5. The method of claim 1, wherein the first oxidation process is followed by forming an oxide layer having a thickness of greater than about 5 Å on a sidewall of the polysilicon pattern.

6. The method of claim 1, wherein the second temperature comprises a temperature of from about 700 to about 900° C.

7. The method of claim 1, wherein performing the second oxidation process comprises performing the second oxidation process using an oxygen gas and a hydrogen gas.

8. The method of claim 1, wherein performing the second oxidation process comprises performing the second oxidation process using water vapor and a hydrogen gas.

9. The method of claim 1, wherein performing the second oxidation process comprises performing the second oxidation process using a furnace type apparatus or a single type apparatus.

10. The method of claim 1, wherein the gate insulation layer pattern comprises silicon oxide or a material having a dielectric constant higher than that of silicon oxide.

11. The method of claim 10, wherein the material comprises HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, CaO and any combination thereof.

12. A method of forming a semiconductor device comprising:
forming a preliminary gate structure on a semiconductor substrate, the preliminary gate structure including a polysilicon layer pattern, a dielectric layer pattern and a conductive layer pattern;
performing a first oxidation process on the preliminary gate structure using an oxygen radical, the first oxidation process being carried out at a first temperature; and
performing a second oxidation process on the preliminary gate structure to form a gate structure on the semiconductor substrate, the second oxidation process being carried out at a second temperature, higher than the first temperature.

13. The method of claim 12, wherein performing the second oxidation process at least partially cures damage to the gate structure caused by an etching process and suppresses oxidation of the conductive layer pattern.

14. The method of claim 13, wherein forming the preliminary gate structure comprises:
forming a preliminary polysilicon layer pattern on the semiconductor substrate;
forming a dielectric layer and a conductive layer on the preliminary polysilicon layer pattern; and
partially etching the preliminary polysilicon layer pattern, the dielectric layer and the conductive layer.

15. The method of claim 14, wherein the conductive layer comprises tungsten.

16. The method of claim 14, wherein forming the conductive layer is preceded by forming a barrier layer on the dielectric layer.

17. The method of claim 12, wherein the first temperature comprises a temperature of from about 200 to about 600° C.

18. The method of claim 12, wherein performing the first oxidation process is preceded by forming an oxide layer having a thickness of from about 5 Å to about 50 Å on a sidewall of the polysilicon pattern.

19. The method of claim 12, wherein the second temperature comprises a temperature of from about 700 to about 900° C.

20. The method of claim 12, wherein performing the second oxidation process comprises performing the second oxidation process using an oxygen gas and a hydrogen gas.

21. The method of claim 12, wherein performing the second oxidation process comprises performing the second oxidation process using water vapor and a hydrogen gas.

22. The method of claim 12, wherein performing the second oxidation process comprises performing the second oxidation process using a furnace type apparatus or a single type apparatus.

23. The method of claim 12, wherein forming the preliminary gate structure is preceded by forming an isolation layer on the substrate to define an active region and a field region of the substrate.

24. The method of claim 12, wherein the dielectric layer pattern comprises a material having a high dielectric constant.

25. The method of claim 24, wherein the material comprises HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, CaO and any combination thereof.
